(19) United States
(12) Patent Application Publication
(10) Pub. No.: US 2026/0206367 A1
(43) Pub. Date: Jul. 16, 2026

(54) PATTERNED PIXELS OF MICRO-LIGHT EMITTING DIODES (uLEDs) AND DIES

(71) Applicant: LUMILEDS LLC, San Jose, CA (US)

(72) Inventors: Toni Lopez, Vaals (NL); Xavier Garcia Santiago, Karlsruhe (DE)

(73) Assignee: LUMILEDS LLC, San Jose, CA (US)

(21) Appl. No.: 19/136,604

(22) PCT Filed: Nov. 28, 2023
(86) PCT No.: PCT/US23/81237

§ 371 Date: Jun. 6, 2025

Related U.S. Application Data
(60) Provisional application No. 63/386,929, filed on Dec. 12, 2022.
(60) Provisional application No. 63/386,931, filed on Dec. 12, 2022.

(51) Int. Cl. H10H 20/821; H10H 20/01; H10H 20/816; H10H 20/857; H10H 29/14

(52) U.S. Cl. CPC H10H 20/821; H10H 20/018; H10H 20/816; H10H 20/857; H10H 29/142

(57) ABSTRACT

A micro-light emitting diode (uLED) comprises: a pixel defined by a mesa of semiconductor layers having sidewall, the mesa including an n-type layer, an active region, and a p-type layer; a patterned feature in the mesa defined by an absence of an epitaxial material from the mesa; a first dielectric material surrounding the sidewall of the pixel; one or more n-contact materials and a common cathode in electrical contact with the n-type layer; and an anode in contact with the p-type layer. MicroLED dies and devices comprising the uLEDs and method of making the same are also provided.

### TECHNICAL FIELD

Embodiments of the disclosure generally relate to micro-light emitting diodes (uLEDs), dies, and devices with the same, and methods of manufacturing and using the same. A uLED comprises a pixel including a patterned feature. MicroLED dies include a plurality of pixels, each of which include a patterned feature. MicroLED devices include the uLED dies, which suitable for hybrid-bonding with target wafers, for example, CMOS wafers, in that there is a combination of a metal-to-metal bonds and dielectric-to-dielectric bonds between the uLED die, which may be referred to as a source wafer, and the target wafer.

### BACKGROUND

Semiconductor light-emitting devices or optical power emitting devices (such as devices that emit ultraviolet (UV) or infrared (IR) optical power), including light emitting diodes, resonant cavity light emitting diodes, vertical cavity laser diodes, and edge emitting lasers, are among the most efficient light sources currently available. Due to their compact size and lower power requirements, for example, semiconductor light or optical power emitting devices (referred to herein as LEDs for simplicity) are attractive candidates for light sources, such as camera flashes, for hand-held battery-powered devices, such as cameras and cell phones. They may also be used, for example, for other applications, such as for automotive lighting, torch for video, and general illumination, such as home, shop, office and studio lighting, theater/stage lighting and architectural lighting.

High-intensity/brightness light emitting devices capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a growth substrate such as a sapphire, silicon carbide, III-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region.

Various emerging display applications, including wearable devices, head-mounted, and large-area displays require miniaturized chips composed of arrays of microLEDs (μLEDs or uLEDs) with a high density having a lateral dimension down to less than 100 μm×100 μm. MicroLEDs (uLEDs) typically have dimensions of about 50 μm in diameter or width and smaller that are used to in the manufacture of color displays by aligning in close proximity microLEDs comprising red, blue and green wavelengths.

Monolithic uLED arrays may require metal (e.g., Al- or Ag-based) side-contacts. These contacts may serve as the electrical cathode for each pixel and also provide reflective sidewalls in between the pixels to reduce light scattering and propagation in lateral directions. With some monolithic uLED architectures, a substrate, sometimes referred to as a “growth” substrate (e.g., sapphire, silicon), may be removed after an array is integrated with a backplane driver and controller combination. This offers multiple advantages such as enhanced light extraction and beam profiling. One typical approach to remove a substrate, for example a sapphire substrate, is by a laser lift-off (LLO) process where a laser beam (UV laser in the case of sapphire substrate) is used to detach the substrate from the epitaxial layers (which were grown on the substrate).

For large-sized emitters, e.g., light emitting diodes (LEDs) of sizes on the order of millimeters and larger, for example 1 mm to 4 mm size emitters, the growth substrate may be patterned with micron scale features (e.g., patterned sapphire substrate or PSS) such that after LLO, a surface of the exposed semiconductor material, e.g., GaN, is textured, which facilitates extraction. With uLED, this is not possible since the PSS features dimensions are too large relative to the pixel size. For pixel sizes of about 1 micrometer, nano-scale PSS may not be feasible for the following reasons: limited space for a periodic arrangement of features, and epitaxial layers being too thick relative to the pixel emitting area.

There is a need for improving and/or maximizing optical efficiency in designs of uLEDs.

### SUMMARY

Provided herein are micro-light emitting diodes (uLEDs), dies, and devices with the same, and methods of manufacturing and using the same.

An aspect provides a micro-light emitting diode (uLED) comprising: a pixel defined by a mesa of semiconductor layers having sidewall, the mesa including an n-type layer, an active region, and a p-type layer; a patterned feature in the mesa defined by an absence of an epitaxial material from the mesa; a first dielectric material surrounding the sidewall of the pixel; one or more n-contact materials and a common cathode in electrical contact with the n-type layer; and an anode in contact with the p-type layer.

In another aspect, micro-light emitting diode (uLED) die comprises: a plurality of pixels each having a sidewall and being defined by a mesa of semiconductor layers, each the mesas including an n-type layer, an active region, and a p-type layer; each of the pixels comprising a patterned feature defined by an absence of an epitaxial material from the mesa; a first dielectric material surrounding the sidewall of each of the pixels; a plurality of n-contact materials between adjacent pixels on the first dielectric material; a common cathode in electrical contact with the n-type layers and the n-contact materials; and a plurality of anodes in contact with each of the p-type layers.

A further aspect is a micro-light emitting diode (uLED) device comprising: a source wafer comprising a micro-light emitting diode (uLED) die comprising: a plurality of pixels each having a sidewall and being defined by a mesa of semiconductor layers, each the mesas including an n-type layer, an active region, and a p-type layer; each of the pixels comprising a patterned feature defined by an absence of an epitaxial material from the mesa; a first dielectric material surrounding the sidewalls of each of the pixels; a plurality of n-contact materials between adjacent pixels on the first dielectric material; a common cathode in electrical contact with the n-type layers and the n-contact materials; and a plurality of anodes in contact with each of the p-type layers; and a target wafer bonded to the source wafer.

An aspect provides a method of manufacturing a micro-light emitting diode (uLED) die comprising: etching pixels of a micro-light emitting diode (uLED) array to prepare a patterned feature in each of the pixels, the uLED array comprising: a plurality of the pixels each being defined by a mesa of semiconductor layers including an n-type layer, an active region, and a p-type layer; a first dielectric material surrounding sidewalls of the pixels; one or more n-contact materials and a common cathode in electrical contact with each of the n-type layers, and an anode in contact with each of the p-type layers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements. The figures herein are not to scale.

FIG. 1 is a schematic view illustrating in cross-section a micro-light emitting diode (uLED) according to one or more embodiments;

FIG. 2 is a schematic view illustrating in cross-section a micro-light emitting diode (uLED) according to one or more embodiments;

FIG. 3 is a schematic view illustrating in cross-section a micro-light emitting diode (uLED) device including uLEDs of FIG. 1 according to one or more embodiments;

FIG. 4 is a schematic view illustrating in cross-section a micro-light emitting diode (uLED) device including uLEDs of FIG. 2 according to one or more embodiments;

FIG. 5 provides a process flow diagram for manufacture of a micro-light emitting diode (uLED) die according to one or more embodiments;

FIG. 6 illustrates a top plan view of an exemplary display device according to one or more embodiments;

FIG. 7 schematically illustrates an exemplary display system comprising uLED devices according to embodiments herein; and

FIG. 8 shows a block diagram of a visualization system according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Reference to LED refers to a light emitting diode that emits light when current flows through it. In one or more embodiments, the LEDs herein have one or more characteristic dimensions (e.g., height, width, depth, thickness, etc. dimensions) in a range of greater than or equal to 75 micrometers to less than or equal to 300 micrometers. In one or embodiments, one or more dimensions of height, width, depth, thickness have values in a range of 100 to 300 micrometers. Reference herein to micrometers allows for variation of ±1-5%. In a preferred embodiment, one or more dimensions of height, width, depth, thickness have values of 200 micrometers ±1-5%. In some instances, the LEDs are referred to as micro-LEDs (uLEDs or μLEDs), referring to a light emitting diode having one or more characteristic dimensions (e.g., height, width, depth, thickness, etc. dimensions) on the order of micrometers or tens of micrometers. In one or embodiments, one or more dimensions of height, width, depth, thickness have values in a range of 1 to less than 75 micrometers, for example from 1 to 50 micrometers, or from 1 to 25 micrometers. Overall, in one or more embodiments, the LEDs herein may have a characteristic dimension ranging from 1 micrometers to 300 micrometers, and all values and sub-ranges therebetween.

LEDs capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a growth substrate such as a sapphire, silicon carbide, III-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region. An LED die is a structure including a substrate and the stack of semiconductor layers.

Methods of depositing materials, layers, and thin films include but are not limited to: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof.

Methods of forming or growing semiconductor layers including n-type layer, active region, and p-type layer are formed according to methods known in the art. In one or more embodiments, the semiconductor layers are formed by epitaxial (EPI) growth. The semiconductor layers according to one or more embodiments comprise epitaxial layers, III-nitride layers, or epitaxial III-nitride layers. In one or more embodiments, the semiconductor layers comprise a III-nitride material, and in specific embodiments epitaxial III-nitride material. In some embodiments, the III-nitride material comprises one or more of gallium (Ga), aluminum (Al), and indium (In). Thus, in some embodiments, the semiconductor layers comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like. The III-nitride materials may be doped with one or more of silicon (Si), oxygen (O), boron (B), phosphorus (P), germanium (Ge), manganese (Mn), or magnesium (Mg) depending upon whether p-type or n-type III-nitride material is needed. In one or more embodiments, the semiconductor layers have a combined thickness in a range of from about 2 μm to about 10 μm, and all values and subranges therebetween.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN and alloys), metal alloys, and other conductive materials, metal phosphides (e.g., InP) depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed are also performed on an underlayer formed on the substrate, and the term “substrate surface” is intended to include such underlayer as the context indicates. Thus for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Suitable applications for uLED devices herein include but are not limited to augmented reality/virtual reality (AR/VR) systems. One or more AR/VR systems include: augmented (AR) or virtual reality (VR) headsets, glasses, or projectors.

MicroLEDS and dies herein include etched-back epitaxial layers down to a lateral extent of the pixel, and patterned light-emitting surface. Such patterning may comprise, or consist of, a patterned feature, e.g., a single nano-scale feature, in the light emitting surface. In one or more embodiments, the feature is in the center of surface. Relative to planar structures of the same pixel size, simulations show that such arrangement can offer 35% total flux gain and nearly 40% flux gain for systems with collection cone angle of 45 deg.

Advantageously, uLEDS and dies and devices including the same herein address problems with uLED arrays and displays including: low light extraction efficiency (ExE), broad angular emission, and limited internal quantum efficiency (IQE). Conventional uLEDS and dies are characterized by planar epitaxial layers such that, after fabrication is completed, the emitting-surface remains unpatterned. This can lead to poor ExE and unfavorable wide angular radiation emission, which is particularly the case of small pixel sizes with steep trench sidewall angles.

MicroLEDS and dies herein primarily aim at preferentially generating light with a narrow angular distribution, on-axis centered and enhance emission by improving both ExE and IQE (i.e. Purcell Effect). This can be effectively etching back the epi and subsequently pattern feature(s). The nano-scale feature(s) on the light-emitting surface, e.g., a GaN surface can efficiently steer the angular emission forward as well as increase the output radiation. Typical nano-scale features may be arranged by etch formation of nanopillars with the nano scale dimensions (e.g. 200 nm height, 200 nm radius on a 1 μm emitter).

The benefits of such etched features are summarized as follows:
Total flux: Increased total power radiated by the pixel by as much as 35% relative to the planar (unpatterned) case. Gains possibly due to enhancement in both Purcell factor and ExE.
Beaming: Increased power radiated within a 60 deg collection angle by as much as 38% relative to the planar (unpatterned). Gains possible due to enhancement in directional angular radiation, ExE and Purcell factor.

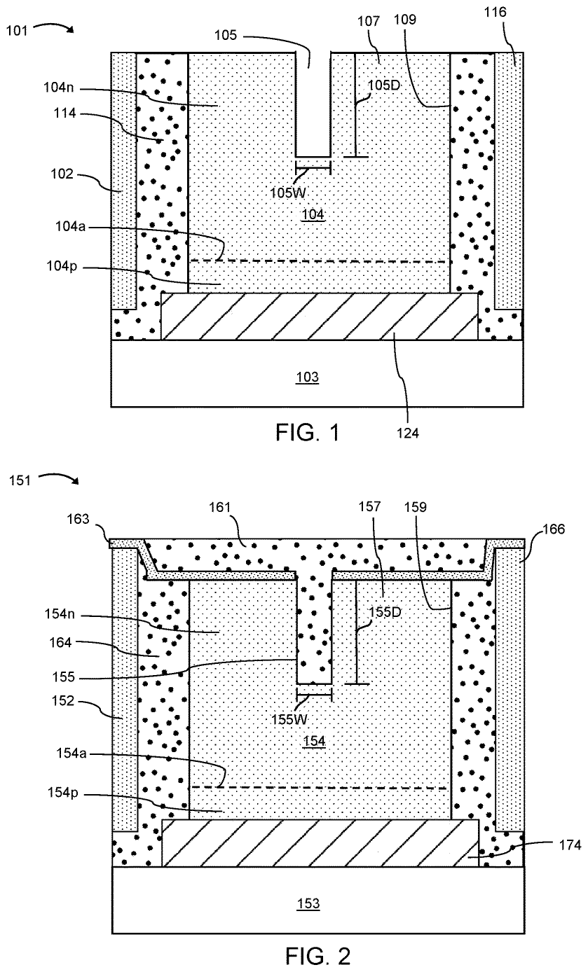

FIG. 1 is a schematic view illustrating in cross-section a micro-light emitting diode (uLED) according to one or more embodiments. The uLED 101 includes a pixel 107 defined by a mesa 104 of semiconductor layers having a sidewall 109, the mesa including an n-type layer 104n, an active region 104a, and a p-type layer 104p. A patterned feature 105 is in the mesa 104 defined by an absence of an epitaxial material from the mesa 104. The patterned feature 105 has a width (or radius) 105W and a depth (or height) 105D. A first dielectric material 114 surrounds the sidewall 109 of the pixel 107. An n-contact material 116 and a common cathode 102 are in electrical contact (not shown in this view) with the n-type layer 104n. An anode 124 is in contact with the p-type layer 104p, and is positioned on a substrate 103.

FIG. 2 is a schematic view illustrating in cross-section a micro-light emitting diode (uLED) according to one or more embodiments. The uLED 151 includes a pixel 157 defined by a mesa 154 of semiconductor layers having a sidewall 159, the mesa including an n-type layer 154n, an active region 154a, and a p-type layer 154p. A patterned feature 155 is in the mesa 154 defined by an absence of an epitaxial material from the mesa 154 and filled with a second dielectric material 161. The patterned feature 155 has a width (or radius) 155W and a depth (or height) 105D. A first dielectric material 164 surrounds the sidewall 159 of the pixel 157. An n-contact material 166 and a common cathode 152 are in electrical contact (not shown in this view) with the n-type layer 154n. An anode 174 is in contact with the p-type layer 154p, and is positioned on a substrate 153. In this embodiment, a current spreading layer 163 is in contact with the n-type layer 154n, the common cathode 152, and the one or more n-contact materials 166. The second dielectric material 161 is on the current spreading layer 163 and in the patterned feature 155.

With reference to both FIGS. 1 and 2, the uLED 101 or 151 the patterned feature 105 or 155 comprises a depth 105D or 155D in a range of 50 nm to 700 nm, including all values and subranges therebetween, and/or a width in a range of 50 nm to 700 nm, including all values and subranges therebetween.

In one or more embodiments, the patterned feature comprises a symmetric shape. In one or more embodiments, the symmetric shape comprises a cylinder. In one or more embodiments, the pixel comprises a single patterned feature. In one or more embodiments, the patterned feature is centered in the pixel. In one or more embodiments, a thickness of the mesa of semiconductor layers is in a range of from 1 μm to 10 μm, and all values and ranges therebetween.

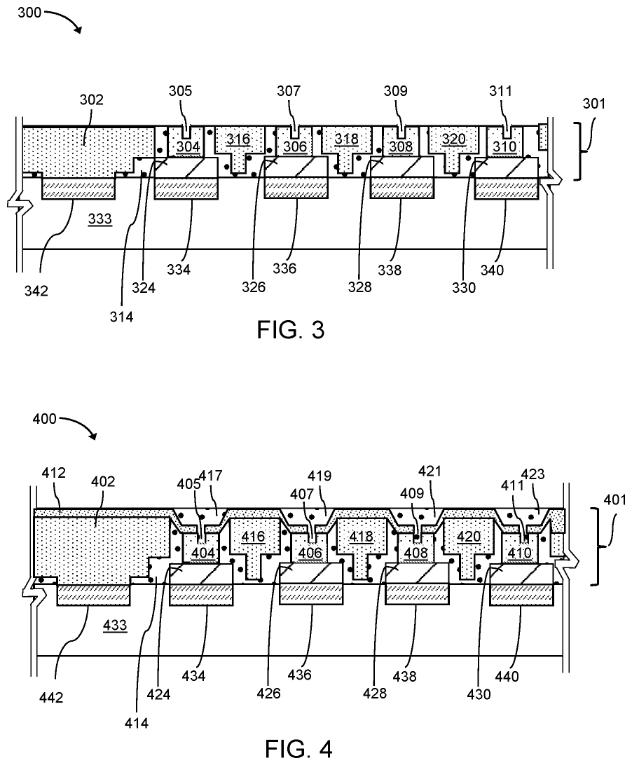

FIG. 3 is a schematic view illustrating in cross-section a micro-light emitting diode (uLED) device including a die with uLEDs of FIG. 1 according to one or more embodiments. The uLED device 400 includes a uLED die 301 comprising a plurality of pixels each having a sidewall (analogously to FIG. 1) and being defined by a mesa 304, 306, 308, 310 of semiconductor layers, each the mesas 304, 306, 308, 310 including an n-type layer, an active region, and a p-type layer. Each of the pixels comprises a patterned feature 305, 307, 309, 311 defined by an absence of an epitaxial material from the mesa 304, 306, 308, 310. A first dielectric material 314 surrounds the sidewall of each of the pixels. A plurality of n-contact materials 316, 318, 320 is positioned between adjacent pixels on the first dielectric material 314. A common electrode 302 is in electrical contact (not shown in this view) with the n-type layers and the n-contact materials 316, 318, 320. A plurality of anodes 324, 326, 328, 330, namely die anodes, are in contact with each of the p-type layers and corresponding contacts or electrodes (anodes) 334, 336, 338, 340 of a substrate 333. The common cathode 302 is in contact with corresponding contact or electrode (cathode) 342 of the substrate 333. In FIG. 3, upper edges of the mesas 304, 306, 308, 310 and the n-contact materials 316, 318, 320 and common cathode 302 are planar. It is understood that other designs may off-set the upper edges of the mesas 304, 306, 308, 310 and the n-contact materials 316, 318, 320 and common cathode 302.

FIG. 4 is a schematic view illustrating in cross-section a micro-light emitting diode (uLED) device including a die with uLEDs of FIG. 2 according to one or more embodiments. The uLED device 400 includes a uLED die 401 comprising a plurality of pixels each having a sidewall (analogously to FIG. 2) and being defined by a mesa 404, 406, 408, 410 of semiconductor layers, each the mesas 404, 406, 408, 410 including an n-type layer, an active region, and a p-type layer. Each of the pixels comprises a patterned feature 405, 407, 409, 411 defined by an absence of an epitaxial material from the mesa 404, 406, 408, 410. A first dielectric material 414 surrounds the sidewall of each of the pixels. A plurality of n-contact materials 416, 418, 420 is positioned between adjacent pixels on the first dielectric material 414. A common electrode 402 is in electrical contact (not shown in this view) with the n-type layers and the n-contact materials 416, 418, 420. A plurality of anodes 424, 426, 428, 430, namely die anodes, are in contact with each of the p-type layers and corresponding contacts or electrodes (anodes) 434, 436, 438, 440 of a substrate 433. The common cathode 402 is in contact with corresponding contact or electrode (cathode) 442 of the substrate 433. A current spreading layer 412 is in contact with the n-type layers of the mesas 404, 406, 408, 410, the common cathode 402, and the one or more n-contact materials 416, 418, 420. A second dielectric material 417, 419, 421, 423 is positioned on portions of the current spreading layer 412 and in the patterned features 405, 407, 409, 411. In FIG. 4, upper edges of the mesas 404, 406, 408, 410 are off-set from upper edges of the n-contact materials 416, 418, 420 and common cathode 402. It is understood that other designs may planarize a combination of the upper edges of the mesas 404, 406, 408, 410 and the n-contact materials 416, 418, 420 and common cathode 402.

With reference to both FIGS. 3 and 4, the uLED die 300 or 400, the patterned features 405, 407, 409, 411 comprises a depth in a range of 50 nm to 700 nm, including all values and subranges therebetween, and/or a width in a range of 50 nm to 700 nm, including all values and subranges therebetween.

In one or more embodiments, a periodicity of the patterned features is in a range of greater than 1 or less than 100 patterned features per pixel, and all values and subranges therebetween.

In one or more embodiments herein, the first and second dielectric material independently comprise one or more of: silicon oxide (SiO), silicon dioxide (SiO2), silicon nitride (SiN), silicon carbide (SiC), aluminum oxide (Al2O3), and aluminum nitride (AlN).

In one or more embodiments herein, the common cathode, the anodes, and the n-contacts, comprise one or more of: copper (Cu), aluminum (Al), nickel (Ni), titanium (Ti), titanium-tungsten (TiW), silver (Ag), gold (Au), platinum (Pt), and palladium (Pd).

In one or more embodiments herein, the current spreading layer comprises indium tin oxide (ITO) and/or indium zinc oxide (IZO).

In one or more embodiments herein, the n-type layer comprises n-GaN and the p-type layer comprises p-GaN.

In one or more embodiments herein, a thickness of n-type layer is in a range of from 0.05 μm to 0.5 μm, and all values and ranges therebetween, and/or a thickness of p-type layer is in a range of from 0.05 μm to 0.5 μm, and all values and ranges therebetween.

With reference to both FIGS. 3 and 4, the substrate 333 and 433, in one or more embodiments, is a target wafer to which die 301 and 401, as a source wafer, are respectively hybrid-bonded. In one or more embodiments, the target wafer is a complementary metal-oxide-semiconductor (CMOS) wafer that is hybrid-bonded to the source wafer in that there is a combination of a metal-to-metal bonds and dielectric-to-dielectric bonds between the source wafer and the target wafer. In one or more embodiments, the target wafer comprises a substrate material selected from the group consisting of: ceramic, silicon, aluminum, a sapphire, silicon carbide, and III-nitride.

According to one or more embodiments, for assembly of the uLED device, a process to achieve hybrid bonding is conducted. That is, a die 301 or 401 is hybrid-bonded to the substrate 333 or 433, which may be a target substrate having target metal contacts or electrodes. Reference to hybrid bonding means that there is a combination of a metal-to-metal bonds and dielectric-to-dielectric bonds.

As to FIG. 3, a surface of each of the anodes 324, 326, 328, 330 is bonded to a surface of each corresponding contacts or electrodes (anodes) 334, 336, 338, 340 of the substrate 333. The common cathode 302 is bonded to contact or electrode (cathode) 342 of the substrate 333. In addition, first dielectric material 314 bonds to a body of the substrate 333, which in one or more embodiments, is a dielectric material.

As to FIG. 4, a surface of each of the anodes 424, 426, 428, 430 is bonded to a surface of each corresponding contacts or electrodes (anodes) 434, 436, 438, 440 of the substrate 433. The common cathode 402 is bonded to contact or electrode (cathode) 442 of the substrate 433. In addition, first dielectric material 414 bonds to a body of the substrate 433, which in one or more embodiments, is a dielectric material.

In one or more embodiments, the target metal contacts comprise one or more of: copper (Cu), aluminum (Al), nickel (Ni), titanium (Ti), titanium-tungsten (TiW), silver (Ag), gold (Au), platinum (Pt), and palladium (Pd).

In one or more embodiments, a substrate body comprises a dielectric material selected from the group consisting of: silicon oxide (SiO), silicon dioxide (SiO₂), silicon nitride (SiN), silicon carbide (SiC), aluminum oxide (Al₂O₃), and aluminum nitride (AlN).

In one or more embodiments, the target substrate further comprises a material selected from the group consisting of: ceramic, silicon, aluminum, sapphire, silicon carbide, and III-nitride.

In one or more embodiments, die anodes are directly bonded to corresponding target wafer electrodes over respective p-contact bond areas, and wherein diameters of the p-contact bond areas have a diameter in a range of 0.5 micrometers to less than or equal to 30 micrometers, including all values and subranges therebetween. In one or more embodiments, a width of each of the die anodes is 95% to 100%, and all values and subranges therebetween of a width of each of the corresponding target wafer electrodes at each location where they are directly bonded, including 95.5%, 96%, 96.5%, 97%, 97.5%, 98%, 98.5%, 99%, 99.1%, 99.2%, 99.2%, 99.3%, 99.4%, 99.5%, 99.6%, 99.7%, 99.8%, 99.9%.

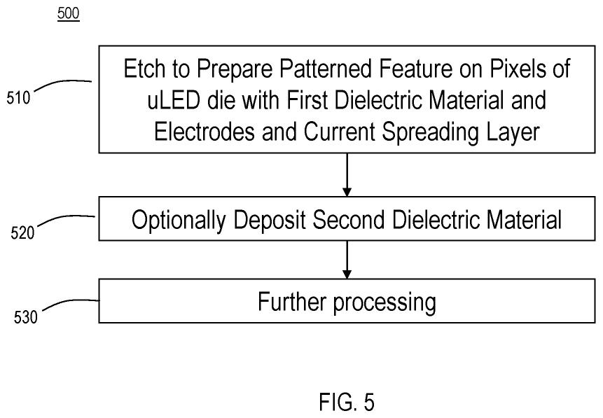

FIG. 5 provides a process flow diagram for manufacture of a micro-light emitting diode (uLED) die according to one or more embodiments. Manufacturing process 500 includes a first operation at 510 where a uLED die having a first dielectric material and electrodes and a current spreading layer is etched at its pixels to prepare a patterned feature in each pixel. In one or more embodiments, the patterning is according to any appropriate technique known to one of skill in the art. According to one or more embodiments, conventional masking, wet etching and/or dry etching processes can be used to for patterning.

At operation 520, optionally a second dielectric material is deposited. Accordingly, the second dielectric material is disposed on portions of the current spreading layer and in the patterned features.

At operation 530, the uLED dies herein are further processed to be bonded to a substrate, e.g., a target wafer.

Thereafter, the uLED devices herein are optionally further processed to include optical elements such as lenses, metalenses, and/or pre-collimators. Optical elements can also or alternatively include apertures, filters, a Fresnel lens, a convex lens, a concave lens, or any other suitable optical element that affects the projected light from the light emitting array. Additionally, one or more of the optical elements can have one or more coatings, including UV blocking or anti-reflective coatings. In some embodiments, optics can be used to correct or minimize two-or three dimensional optical errors including pincushion distortion, barrel distortion, longitudinal chromatic aberration, spherical aberration, chromatic aberration, field curvature, astigmatism, or any other type of optical error. In some embodiments, optical elements can be used to magnify and/or correct images. Advantageously, in some embodiments magnification of display images allows the light emitting array to be physically smaller, of less weight, and require less power than larger displays. Additionally, magnification can increase a field of view of the displayed content allowing display presentation equals a user's normal field of view.

### uLED Devices

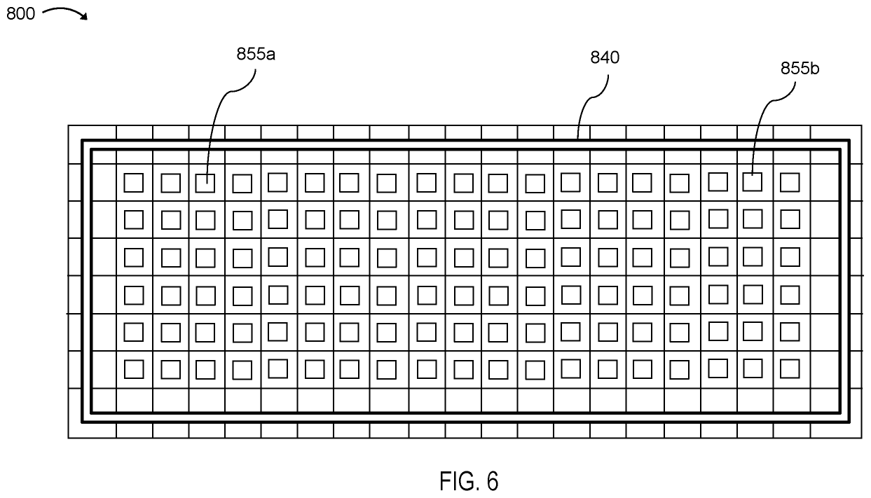

FIG. 6 shows a top plan view of an exemplary uLED display device comprising a uLED monolithic array 800 comprising a plurality of pixels arranged in a grid of 6×19. Pixels 855a and 855b are examples. In this embodiment, a common cathode 840 is connected to the pixels. Anodes, not shown, present on the underside are included with each pixel. In one or more embodiments, the array comprises an arrangement of 2×2 mesas, 4×4 mesas, 20×20 mesas, 50×50 mesas, 100×100 mesas, or n1×n2 mesas, where each of n1 and n2is a number in a range of from 2 to 1000, and n1 and n2 can be equal or not equal.

In one or more embodiments, arrays of micro-LEDs (μLEDs or uLEDs) are used. Micro-LEDs can support high density pixels having a lateral dimension less than 100 μm by 100 μm. In some embodiments, micro-LEDs with dimensions of about 50 μm in diameter or width and smaller can be used. Such micro-LEDs can be used for the manufacture of color displays by aligning in close proximity micro-LEDs comprising red, blue and green wavelengths.

In some embodiments, the light emitting arrays include small numbers of micro-LEDs positioned on substrates that are centimeter scale area or greater. In some embodiments, the light emitting arrays include micro-LED pixel arrays with hundreds, thousands, or millions of light emitting LEDs positioned together on centimeter scale area substrates or smaller. In some embodiments, micro-LEDs can include light emitting diodes sized between 30 microns and 500 microns. The light emitting array(s) can be monochromatic, RGB, or other desired chromaticity. In some embodiments, pixels can be square, rectangular, hexagonal, or have curved perimeter. Pixels can be of the same size, of differing sizes, or similarly sized and grouped to present larger effective pixel size.

In some embodiments, light emitting pixels and circuitry supporting light emitting arrays are packaged and optionally include a submount or printed circuit board connected for powering and controlling light production by semiconductor LEDs. In certain embodiments, a printed circuit board supporting light emitting array includes electrical vias, heat sinks, ground planes, electrical traces, and flip chip or other mounting systems. The submount or printed circuit board may be formed of any suitable material, such as ceramic, silicon, aluminum, etc. If the submount material is conductive, an insulating layer is formed over the substrate material, and the metal electrode pattern is formed over the insulating layer. The submount can act as a mechanical support, providing an electrical interface between electrodes on the light emitting array and a power supply, and also provide heat sink functionality.

In some embodiments, LED light emitting arrays include optical elements such as lenses, metalenses, and/or pre-collimators. Optical elements can also or alternatively include apertures, filters, a Fresnel lens, a convex lens, a concave lens, or any other suitable optical element that affects the projected light from the light emitting array. Additionally, one or more of the optical elements can have one or more coatings, including UV blocking or anti-reflective coatings. In some embodiments, optics can be used to correct or minimize two-or three dimensional optical errors including pincushion distortion, barrel distortion, longitudinal chromatic aberration, spherical aberration, chromatic aberration, field curvature, astigmatism, or any other type of optical error. In some embodiments, optical elements can be used to magnify and/or correct images. Advantageously, in some embodiments magnification of display images allows the light emitting array to be physically smaller, of less weight, and require less power than larger displays. Additionally, magnification can increase a field of view of the displayed content allowing display presentation equals a user's normal field of view.

### APPLICATIONS

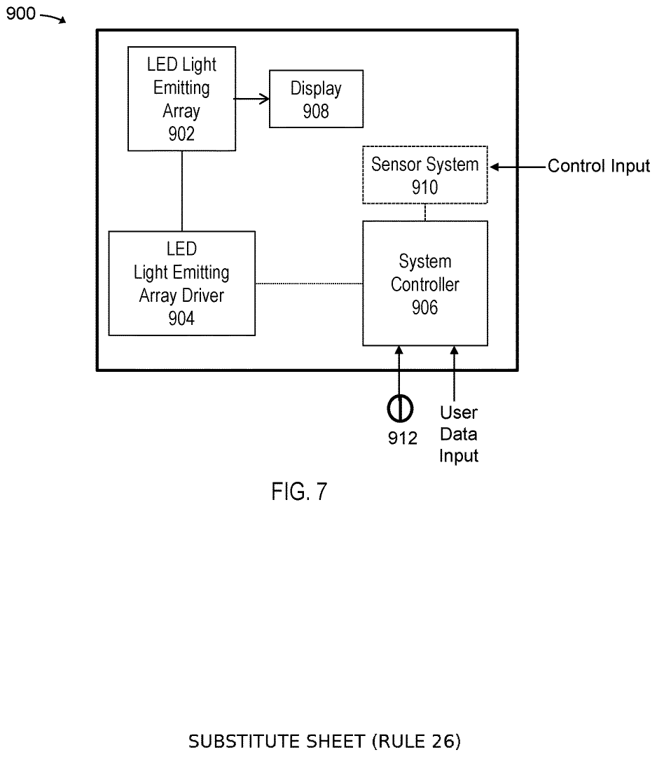

FIG. 7 schematically illustrates an exemplary display system 900 utilizing LEDs, including uLEDs, disclosed herein. The display system 900 comprises an LED light emitting array 902 and display 908 in electrical communication with an LED driver 904. The display system 900 also comprises a system controller 906, such as a microprocessor. The controller 906 is coupled to the LED driver 904. The controller 906 may also be coupled to the display 908 and to optional sensor(s) 910, and be powered by power source 912. In one or more embodiments, user data input is provided to system controller 906.

In one or more embodiments, the system is a camera flash system utilizing uLEDs. In such an embodiment, the LED light emitting array 902 is an illumination array and lens system and the display 908 comprises a camera, wherein the LEDs of 902 and the camera of 908 may be controlled by the controller 906 to match their fields of view.

Optionally sensors 910 with control input may include, for example, positional sensors (e.g., a gyroscope and/or accelerometer) and/or other sensors that may be used to determine the position, speed, and orientation of system. The signals from the sensors 910 may be supplied to the controller 906 to be used to determine the appropriate course of action of the controller 906 (e.g., which LEDs are currently illuminating a target and which LEDs will be illuminating the target a predetermined amount of time later).

In operation, illumination from some or all of the pixels of the LED array in 902 may be adjusted-deactivated, operated at full intensity, or operated at an intermediate intensity. As noted above, beam focus or steering of light emitted by the LED array in 902 can be performed electronically by activating one or more subsets of the pixels, to permit dynamic adjustment of the beam shape without moving optics or changing the focus of the lens in the lighting apparatus.

LED array systems such as described herein may support various other beam steering or other applications that benefit from fine-grained intensity, spatial, and temporal control of light distribution. These applications may include, but are not limited to, precise spatial patterning of emitted light from pixel blocks or individual pixels. Depending on the application, emitted light may be spectrally distinct, adaptive over time, and/or environmentally responsive. The light emitting pixel arrays may provide pre-programmed light distribution in various intensity, spatial, or temporal patterns. Associated optics may be distinct at a pixel, pixel block, or device level. An example light emitting pixel array may include a device having a commonly controlled central block of high intensity pixels with an associated common optic, whereas edge pixels may have individual optics. In addition to flashlights, common applications supported by light emitting pixel arrays include video lighting, automotive headlights, architectural and area illumination, and street lighting.

Other applications of LED devices herein include augmented reality/virtual reality (AR/VR) systems, which may utilize uLEDs disclosed herein. One or more AR/VR systems include: augmented (AR) or virtual reality (VR) headsets, glasses, or projectors. Such AR/VR systems includes an LED light emitting array, an LED driver (or light emitting array controller), a system controller, an AR or VR display, a sensor system 810. Control input may be provided to the sensor system, while power and user data input is provided to the system controller. As will be understood, in some embodiments modules included in the AR/VR system can be compactly arranged in a single structure, or one or more elements can be separately mounted and connected via wireless or wired communication. For example, the light emitting array, AR or VR display, and sensor system can be mounted on a headset or glasses, with the LED driver and/or system controller separately mounted.

In one embodiment, the light emitting array can be used to project light in graphical or object patterns that can support AR/VR systems. In some embodiments, separate light emitting arrays can be used to provide display images, with AR features being provided by a distinct and separate micro-LED array. In some embodiments, a selected group of pixels can be used for displaying content to the user while tracking pixels can be used for providing tracking light used in eye tracking. Content display pixels are designed to emit visible light, with at least some portion of the visible band (approximately 400 nm to 750 nm). In contrast, tracking pixels can emit light in visible band or in the IR band (approximately 750 nm to 2,200 nm), or some combination thereof. As an alternative example, the tracking pixels could operate in the 800 to 1000 nanometer range. In some embodiments, the tracking pixels can emit tracking light during a time period that content pixels are turned off and are not displaying content to the user.

The AR/VR system can incorporate a wide range of optics in the LED light emitting array and/or AR/VR display, for example to couple light emitted by the LED light emitting array into AR/VR display as discussed above. For AR/VR applications, these optics may comprise nanofins and be designed to polarize the light they transmit.

In one embodiment, the light emitting array controller can be used to provide power and real time control for the light emitting array. For example, the light emitting array controller can be able to implement pixel or group pixel level control of amplitude and duty cycle. In some embodiments, the light emitting array controller further includes a frame buffer for holding generated or processed images that can be supplied to the light emitting array. Other supported modules can include digital control interfaces such as Inter-Integrated Circuit (I2C) serial bus, Serial Peripheral Interface (SPD), USB-C, HDMI, Display Port, or other suitable image or control modules that are configured to transmit needed image data, control data or instructions.

In operation, pixels in the images can be used to define response of corresponding light emitting array, with intensity and spatial modulation of LED pixels being based on the image(s). To reduce data rate issues, groups of pixels (e.g. 5×5 blocks) can be controlled as single blocks in some embodiments. In some embodiments, high speed and high data rate operation is supported, with pixel values from successive images able to be loaded as successive frames in an image sequence at a rate between 30 Hz and 100 Hz, with 60 Hz being typical. Pulse width modulation can be used to control each pixel to emit light in a pattern and with an intensity at least partially dependent on the image.

In some embodiments, the sensor system can include external sensors such as cameras, depth sensors, or audio sensors that monitor the environment, and internal sensors such as accelerometers or two or three axis gyroscopes that monitor AR/VR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position. As another example, based on the one or more measurement signals from one or more gyroscope or position sensors that measure translation or rotational movement, an estimated position of AR/VR system relative to an initial position can be determined.

In some embodiments, the system controller uses data from the sensor system to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow.

Based on changes in position, orientation, or movement of the AR/VR system, the system controller can send images or instructions the light emitting array controller. Changes or modification in the images or instructions can also be made by user data input, or automated data input as needed. User data input can include but is not limited to that provided by audio instructions, haptic feedback, eye or pupil positioning, or connected keyboard, mouse, or game controller.

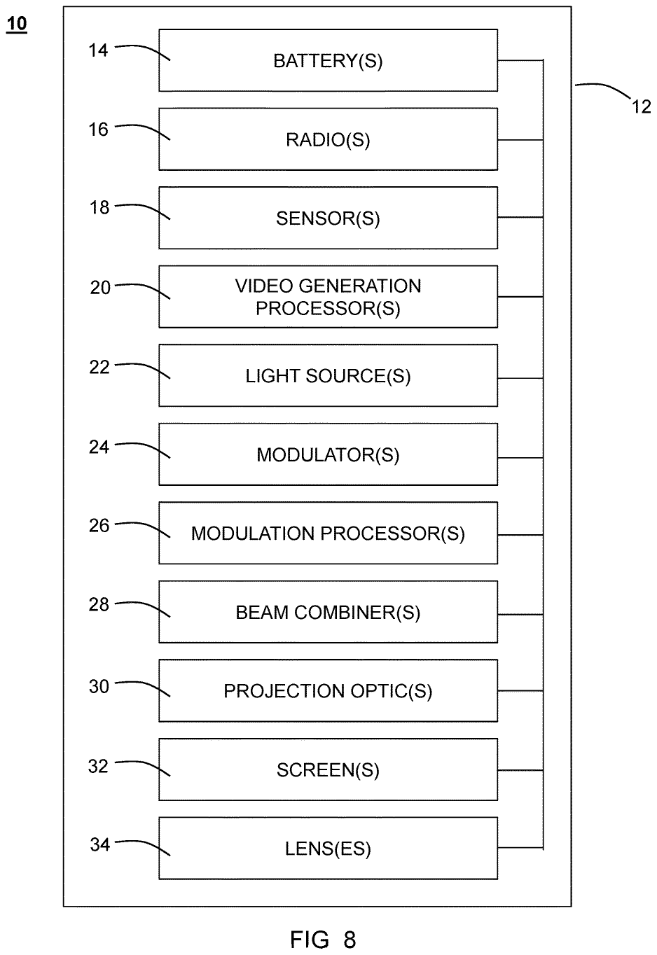

FIG. 8 shows a block diagram of an example of a visualization system 10. The visualization system 10 can include a wearable housing 12, such as a headset or goggles. The housing 12 can mechanically support and house the elements detailed below. In some examples, one or more of the elements detailed below can be included in one or more additional housings that can be separate from the wearable housing 12 and couplable to the wearable housing 12 wirelessly and/or via a wired connection. For example, a separate housing can reduce the weight of wearable goggles, such as by including batteries, radios, and other elements. The housing 12 can include one or more batteries 14, which can electrically power any or all of the elements detailed below. The housing 12 can include circuitry that can electrically couple to an external power supply, such as a wall outlet, to recharge the batteries 14. The housing 12 can include one or more radios 16 to communicate wirelessly with a server or network via a suitable protocol, such as WiFi.

The visualization system 10 can include one or more sensors 18, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 18 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 18 can capture a real-time video image of the surroundings proximate a user.

The visualization system 10 can include one or more video generation processors 20. The one or more video generation processors 20 can receive, from a server and/or a storage medium, scene data that represents a three-dimensional scene, such as a set of position coordinates for objects in the scene or a depth map of the scene. The one or more video generation processors 20 can receive one or more sensor signals from the one or more sensors 18. In response to the scene data, which represents the surroundings, and at least one sensor signal, which represents the location and/or orientation of the user with respect to the surroundings, the one or more video generation processors 20 can generate at least one video signal that corresponds to a view of the scene. In some examples, the one or more video generation processors 20 can generate two video signals, one for each eye of the user, that represent a view of the scene from a point of view of the left eye and the right eye of the user, respectively. In some examples, the one or more video generation processors 20 can generate more than two video signals and combine the video signals to provide one video signal for both eyes, two video signals for the two eyes, or other combinations.

The visualization system 10 can include one or more light sources 22 that can provide light for a display of the visualization system 10. Suitable light sources 22 can include a light-emitting diode, a monolithic light-emitting diode, a plurality of light-emitting diodes, an array of light-emitting diodes, an array of light-emitting diodes disposed on a common substrate, a segmented light-emitting diode that is disposed on a single substrate and has light-emitting diode elements that are individually addressable and controllable (and/or controllable in groups and/or subsets), an array of micro-light-emitting diodes (microLEDs), and others.

A light-emitting diode can be white-light light-emitting diode. For example, a white-light light-emitting diode can emit excitation light, such as blue light or violet light. The white-light light-emitting diode can include one or more phosphors that can absorb some or all of the excitation light and can, in response, emit phosphor light, such as yellow light, that bas a wavelength greater than a wavelength of the excitation light.

The one or more light sources 22 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The visualization system 10 can include one or more modulators 24. The modulators 24 can be implemented in one of at least two configurations.

In a first configuration, the modulators 24 can include circuitry that can modulate the light sources 22 directly. For example, the light sources 22 can include an array of light-emitting diodes, and the modulators 24 can directly modulate the electrical power, electrical voltage, and/or electrical current directed to each light-emitting diode in the array to form modulated light. The modulation can be performed in an analog manner and/or a digital manner. In some examples, the light sources 22 can include an array of red light-emitting diodes, an array of green light-emitting diodes, and an array of blue light-emitting diodes, and the modulators 24 can directly modulate the red light-emitting diodes, the green light-emitting diodes, and the blue light-emitting diodes to form the modulated light to produce a specified image.

In a second configuration, the modulators 24 can include a modulation panel, such as a liquid crystal panel. The light sources 22 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 24 can include multiple modulation panels that can modulate different colors of light. For example, the modulators 24 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 24 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 10 can include one or more modulation processors 26, which can receive a video signal, such as from the one or more video generation processors 20, and, in response, can produce an electrical modulation signal. For configurations in which the modulators 24 directly modulate the light sources 22, the electrical modulation signal can drive the light sources 24. For configurations in which the modulators 24 include a modulation panel, the electrical modulation signal can drive the modulation panel.

The visualization system 10 can include one or more beam combiners 28 (also known as beam splitters 28), which can combine light beams of different colors to form a single multi-color beam. For configurations in which the light sources 22 can include multiple light-emitting diodes of different colors, the visualization system 10 can include one or more wavelength-sensitive (e.g., dichroic) beam splitters 28 that can combine the light of different colors to form a single multi-color beam.

The visualization system 10 can direct the modulated light toward the eyes of the viewer in one of at least two configurations. In a first configuration, the visualization system 10 can function as a projector, and can include suitable projection optics 30 that can project the modulated light onto one or more screens 32. The screens 32 can be located a suitable distance from an eye of the user. The visualization system 10 can optionally include one or more lenses 34 that can locate a virtual image of a screen 32 at a suitable distance from the eye, such as a close-focus distance, such as 500 mm, 750 mm, or another suitable distance. In some examples, the visualization system 10 can include a single screen 32, such that the modulated light can be directed toward both eyes of the user. In some examples, the visualization system 10 can include two screens 32, such that the modulated light from each screen 32 can be directed toward a respective eye of the user. In some examples, the visualization system 10 can include more than two screens 32. In a second configuration, the visualization system 10 can direct the modulated light directly into one or both eyes of a viewer. For example, the projection optics 30 can form an image on a retina of an eye of the user, or an image on each retina of the two eyes of the user.

### EMBODIMENTS

Various embodiments are listed below. It will be understood that the embodiments listed below may be combined with all aspects and other embodiments in accordance with the scope of the invention.
Embodiment (a) A micro-light emitting diode (uLED) comprising: a pixel defined by a mesa of semiconductor layers having sidewall, the mesa including an n-type layer, an active region, and a p-type layer; a patterned feature in the mesa defined by an absence of an epitaxial material from the mesa; a first dielectric material surrounding the sidewall of the pixel; one or more n-contact materials and a common cathode in electrical contact with the n-type layer; and an anode in contact with the p-type layer.
Embodiment (b) The uLED of embodiment (a) further comprising: a current spreading layer in contact with the n-type layer, the common cathode, and the one or more n-contact materials.
Embodiment (c) The uLED of embodiment (b) further comprising: a second dielectric material on the current spreading layer and in the patterned feature.
Embodiment (d) The uLED of any of embodiments (a) to (c), wherein the patterned feature comprises a depth in a range of 50 nm to 700 nm, and/or a width in a range of 50 nm to 700 nm.
Embodiment (e) The uLED of any of embodiments (a) to (d), wherein the patterned feature comprises a symmetric shape.
Embodiment (f) The uLED of embodiment (e), wherein the symmetric shape comprises a cylinder.
Embodiment (g) The uLED of any of embodiments (a) to (f), wherein the pixel comprises a single patterned feature.
Embodiment (h) The uLED of embodiment (g), wherein the patterned feature is centered in the pixel.
Embodiment (i) The uLED of any of embodiments (a) to (h), wherein a thickness of the mesa is in a range of from 1 μm to 10 μm.
Embodiment (j) A micro-light emitting diode (uLED) die comprising: a plurality of pixels each having a sidewall and being defined by a mesa of semiconductor layers, cach the mesas including an n-type layer, an active region, and a p-type layer; each of the pixels comprising a patterned feature defined by an absence of an epitaxial material from the mesa; a first dielectric material surrounding the sidewall of each of the pixels; a plurality of n-contact materials between adjacent pixels on the first dielectric material; a common cathode in electrical contact with the n-type layers and the n-contact materials; and a plurality of anodes in contact with each of the p-type layers.
Embodiment (k) The uLED die of embodiment (j) further comprising: a current spreading layer in contact with the n-type layer, the common cathode, and the plurality of n-contact materials.
Embodiment (l) The uLED die of embodiment (k) further comprising: a second dielectric material on portions of the current spreading layer and in each of the patterned features.
Embodiment (m) The uLED die of any of embodiments (j) to (l), wherein the patterned feature comprises a depth in a range of 50 nm to 700 nm, and/or a width in a range of 50 nm to 700 nm.
Embodiment (n) The uLED die of any of embodiments (j) to (m), wherein the patterned feature comprises a symmetric shape.
Embodiment (o) The uLED die of embodiment (n), wherein the symmetric shape comprises a cylinder.
Embodiment (p) The uLED die of any of embodiments (j) to (o), wherein each pixel comprises a single patterned feature.
Embodiment (q) The uLED die of embodiment (p), wherein the patterned feature is centered in the pixel.
Embodiment (r) The uLED die of any of embodiments (j) to (q), comprising a periodicity of the patterned features in a range of greater than 1 or less than 100 of the patterned features per pixel.
Embodiment(s) The uLED die of any of embodiments (j) to (r), wherein a thickness of the mesa of semiconductor layers is in a range of from 1 μm to 10 μm.
Embodiment (t) The uLED die of any of embodiments (j) to(s), wherein the first and second dielectric material independently comprise one or more of: silicon oxide (SiO), silicon dioxide (SiO₂), silicon nitride (SiN), silicon carbide (SiC), aluminum oxide (Al₂O₃), and aluminum nitride (AlN).
Embodiment (u) The uLED or uLED device of any foregoing embodiment, wherein the common cathode, the anodes, and the n-contacts, comprise one or more of: copper (Cu), aluminum (Al), nickel (Ni), titanium (Ti), titanium-tungsten (TiW), silver (Ag), gold (Au), platinum (Pt), and palladium (Pd).
Embodiment (v) The uLED or uLED device of any foregoing embodiment, wherein the current spreading layer comprises indium tin oxide (ITO) and/or indium zinc oxide (IZO).
Embodiment (w) The uLED or uLED device of any foregoing embodiment, wherein the n-type layer comprises n-GaN and the p-type layer comprises p-GaN.

The uLED or uLED of any foregoing embodiment, wherein a thickness of the n-type layer is in a range of from 0.05 μm to 0.5 μm, and/or a thickness of the p-type layer is in a range of from 0.05 μm to 0.5 μm. Embodiment (aa) A micro-light emitting diode (uLED) device comprising: a source wafer comprising a micro-light emitting diode (uLED) die comprising: a plurality of pixels cach having a sidewall and being defined by a mesa of semiconductor layers, each the mesas including an n-type layer, an active region, and a p-type layer; each of the pixels comprising a patterned feature defined by an absence of an epitaxial material from the mesa; a first dielectric material surrounding the sidewalls of each of the pixels; a plurality of n-contact materials between adjacent pixels on the first dielectric material; a common cathode in electrical contact with the n-type layers and the n-contact materials; and a plurality of anodes in contact with each of the p-type layers; and a target wafer bonded to the source wafer.
Embodiment (bb) The uLED device of embodiment (aa), wherein the target wafer is a complementary metal-oxide semiconductor (CMOS) wafer that is hybrid-bonded to the source wafer in that there is a combination of a metal-to-metal bonds and dielectric-to-dielectric bonds between the source wafer and the target wafer.
Embodiment (cc) The uLED device of embodiment (aa) or (bb), wherein the target wafer comprises a substrate material selected from the group consisting of: ceramic, silicon, aluminum, a sapphire, silicon carbide, and III-nitride.
Embodiment (dd) The uLED device of any of embodiments (aa) to (cc) further comprising: a current spreading layer in contact with the n-type layer, the common cathode, and the n-contact materials.
Embodiment (ee) The uLED device of embodiment (dd) further comprising: a second dielectric material on the current spreading layer and in the patterned feature.
Embodiment (ff) The uLED device of any of embodiments (aa) to (ee). wherein the patterned feature comprises a symmetric shape.
Embodiment (gg) The uLED device of embodiment (ff), wherein the symmetric shape comprises a cylinder.
Embodiment (hh) The uLED device of any of embodiments (aa) to (gg), wherein each of the pixels comprises a single patterned feature.
Embodiment (ii) The uLED device of embodiment (hh), wherein the patterned feature is centered in the pixel.
Embodiment (jj) The uLED device of any of embodiments (aa) to (ii) wherein a thickness of the mesa is in a range of from 1 μm to 10 μm.
Embodiment (kk) A method of manufacturing a micro-light emitting diode (uLED) die comprising: etching pixels of a micro-light emitting diode (uLED) array to prepare a patterned feature in each of the pixels, the uLED array comprising: a plurality of the pixels each being defined by a mesa of semiconductor layers including an n-type layer, an active region, and a p-type layer; a first dielectric material surrounding sidewalls of the pixels; one or more n-contact materials and a common cathode in electrical contact with each of the n-type layers, and an anode in contact with each of the p-type layers.
Embodiment (ll) The method of embodiment (kk), wherein the uLED array further comprises: a current spreading layer in contact with the n-type layer, the common cathode, and the one or more n-contact materials.
Embodiment (mm) The method of embodiment (ll), wherein the method further comprises depositing a second dielectric material onto the uLED array, the second dielectric material is disposed on the current spreading layer and in the patterned feature.
Embodiment (nn) The method of any of embodiments (kk) to (mm), wherein the patterned feature comprises a depth in a range of 50 nm to 700 nm, and/or a width in a range of 50 nm to 700 nm.
Embodiment (oo) The method of any of embodiments (kk) to (nn), wherein the patterned feature comprises a symmetric shape.
Embodiment (pp) The method of embodiment (oo), wherein the symmetric shape comprises a cylinder.
Embodiment (qq) The method of any of embodiments (kk) to (pp), wherein each of the pixels comprises a single patterned feature.
Embodiment (rr) The method of embodiment (qq), wherein the patterned feature is centered in the pixel.
Embodiment (ss) The method of any of embodiments (kk) to (rr) comprising preparing the patterned features with a periodicity of in a range of greater than 1 or less than 100 of the patterned features per pixel.

The method of any of embodiments (kk) to (ss), wherein a thickness of the mesa of semiconductor layers is in a range of from 1 μm to 10 μm.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

1. A micro-light emitting diode (uLED) comprising:
a pixel defined by a mesa of semiconductor layers having sidewall, the mesa including an n-type layer, an active region, and a p-type layer;
a patterned feature in the mesa defined by an absence of an epitaxial material from the mesa;
a first dielectric material surrounding the sidewall of the pixel;
one or more n-contact materials and a common cathode in electrical contact with the n-type layer; and
an anode in contact with the p-type layer.

2. The uLED of claim 1 further comprising: a current spreading layer in contact with the n-type layer, the common cathode, and the one or more n-contact materials, and/or a second dielectric material on the current spreading layer and in the patterned feature.

3. The uLED of claim 1, wherein the patterned feature comprises a depth in a range of 50 nm to 700 nm, and/or a width in a range of 50 nm to 700 nm.

4. The uLED of claim 1, wherein the patterned feature comprises a symmetric shape.

5. The uLED of claim 1, wherein the pixel comprises a single patterned feature.

6. The uLED of claim 1, wherein a thickness of the mesa is in a range of from 1 μm to 10 μm.

7. A micro-light emitting diode (uLED) die comprising:
a plurality of pixels each having a sidewall and being defined by a mesa of semiconductor layers, each the mesas including an n-type layer, an active region, and a p-type layer;
each of the pixels comprising a patterned feature defined by an absence of an epitaxial material from the mesa;
a first dielectric material surrounding the sidewall of each of the pixels;
a plurality of n-contact materials between adjacent pixels on the first dielectric material;
a common cathode in electrical contact with the n-type layers and the n-contact materials; and
a plurality of anodes in contact with each of the p-type layers.

8. The uLED die of claim 7 further comprising: a current spreading layer in contact with the n-type layer, the common cathode, and the plurality of n-contact materials, and/or a second dielectric material on portions of the current spreading layer and in each of the patterned features.

9. The uLED die of claim 7, wherein the patterned feature comprises a depth in a range of 50 nm to 700 nm, and/or a width in a range of 50 nm to 700 nm.

10. The uLED die of claim 7, wherein the patterned feature comprises a symmetric shape.

11. The uLED die of claim 7, wherein each pixel comprises a single patterned feature.

12. The uLED die of claim 7 comprising a periodicity of the patterned features in a range of greater than 1 or less than 100 of the patterned features per pixel.

13. The uLED die of claim 7, wherein a thickness of the mesa of semiconductor layers is in a range of from 1 μm to 10 μm.

14. The uLED die of claim 7, wherein the first and second dielectric material independently comprise one or more of: silicon oxide (SiO), silicon dioxide (SiO₂), silicon nitride (SiN), silicon carbide (SiC), aluminum oxide (Al₂O₃), and aluminum nitride (AlN).

15. A micro-light emitting diode (uLED) device comprising:
a source wafer comprising a micro-light emitting diode (uLED) die comprising:
a plurality of pixels each having sidewalls and being defined by a mesa of semiconductor layers, each the mesas including an n-type layer, an active region, and a p-type layer;
each of the pixels comprising a patterned feature defined by an absence of an epitaxial material from the mesa;
a first dielectric material surrounding the sidewalls of each of the pixels;
a plurality of n-contact materials between adjacent pixels on the first dielectric material;
a common cathode in electrical contact with the n-type layers and the n-contact materials; and
a plurality of anodes in contact with each of the p-type layers; and
a target wafer bonded to the source wafer.

16. The uLED device of claim 15, wherein the target wafer is a complementary metal-oxide-semiconductor (CMOS) wafer that is hybrid-bonded to the source wafer in that there is a combination of a metal-to-metal bonds and dielectric-to-dielectric bonds between the source wafer and the target wafer.

17. The uLED device of claim 15, wherein the target wafer comprises a substrate material selected from the group consisting of: ceramic, silicon, aluminum, a sapphire, silicon carbide, and III-nitride.

18. The uLED device of claim 15 further comprising: a current spreading layer in contact with the n-type layer, the common cathode, and the one or more n-contact materials, and/or a second dielectric material on the current spreading layer and in the patterned feature.

19. The uLED device of claim 15, wherein the patterned feature comprises a symmetric shape.

20. The uLED device of claim 15, wherein the pixel comprises a single patterned feature.
